(19) United States
(12) Patent Application Publication
(10) Pub. No.: US 2008/0305275 A1
(43) Pub. Date: Dec. 11, 2008

(54) CVD system and substrate cleaning method

(75) Inventors: Kazuo Ichikawa, Fuchu-shi (JP); Hiroshi Tanabe, Tokyo (JP); Katsuhisa Yuda, Tokyo (JP)

Correspondence Address: OLIFF & BERRIDGE, PLC, P.O. BOX 320850, ALEXANDRIA, VA, 22320-4850, US

(73) Assignee: CANON ANELVA CORPORATION, Kawasaki-shi (JP)

(21) Appl. No.: 12/216,598

(22) Filed: Jul. 8, 2008

Related U.S. Application Data
(62) Division of application No. 11/907,366, filed on Oct. 11, 2007.
Application No. 11/907,366 is a continuation of application No. 09/670,877, filed on Sep. 27, 2000, now abandoned.

(30) Foreign Application Priority Data
Sep. 28, 1999 (JP) 11-274216

(51) Int. Cl. C23C 16/453

(52) U.S. Cl. 427/569

(57) ABSTRACT

An insulating film deposition chamber 40 has a plasma generator 14 having a plasma generation chamber 21 separated from the film deposition chamber 13 in which the substrate is arranged. A material gas is directly supplied to the film deposition chamber, and radicals are introduced into the film deposition chamber from the plasma generator, and a thin film is deposited on the substrate. Further, a cleaning gas feeder is added to the plasma generator. A cleaning gas is introduced through the cleaning gas feeder to produce plasma at the plasma generator to generate radicals, and the radicals are introduced into the film deposition chamber and irradiate the substrate to clean it.

This is a Divisional of application Ser. No. 11/907,366, filed Oct. 11, 2007, which is a Continuation of application Ser. No. 09/670,877 filed Sep. 27, 2000. This application claims the benefit of Japanese Patent Application No. 11-274216, filed on Sep. 28, 1999. The disclosures of the prior applications are hereby incorporated by reference herein in their entirety.

### BACKGROUND

1. Field of the Invention

The present invention relates to a chemical vapor deposition (CVD) system and a substrate cleaning method, more particularly, relates to a CVD system comprising a separate film deposition chamber and a plasma generation chamber, and being easily able to clean a substrate at a suitable timing, and a substrate cleaning method used for the system.

2. Description of the Related Art

As the process of depositing a film on a substrate with a relatively large area to produce thin film transistors used for a liquid crystal display etc., the method of forming a silicon-based film (amorphous silicon etc.) on a substrate, converting the silicon-based film to a polycrystalline silicon film by laser annealing, and forming a gate insulating film on the polycrystalline silicon film by plasma CVD etc. is known. Note that as the film deposition system used for the plasma CVD, there is a plasma isolation type system comprised of a separate film-deposition chamber and plasma generation chamber. In this system, the film deposition chamber and the plasma generation chamber are spatially separated. The two spaces are communicated through only radical introduction through holes. This system prevents the plasma from dispersing and contacting the substrate placed in the film-deposition chamber. In the plasma generation chamber, radicals are generated by the plasma. Only the radicals are introduced through the through holes to the film-deposition chamber and strike the substrate.

In case of heating the silicon-based film by laser annealing as explained above and then forming a gate insulating film by the film deposition system, it has been known that a good interface can be obtained by reducing the amount of the impurity deposited on the surface of the silicon based film on which the gate insulating film is deposited. Therefore, as the method of forming the insulating film, there has been the method of H₂ plasma treatment as pre-treatment for forming the insulating film (for example, Japanese Unexamined Patent Publication (Kokai) No. 9-116166). Further, according to this method, the pre-treatment chamber for forming the insulating film is provided as a separate vacuum chamber independent from the film deposition chamber for depositing the insulating film.

The conventional method reduces the amount of impurity deposited on the surface on which the insulating film should be formed by use of the H₂ plasma treatment. Therefore, the conventional method poses the problem that the charged particles struck the interface and damaged the silicon of the active layer and therefore had a detrimental effect on the performance of the product. Further, since a system utilizing the H₂ plasma treatment needs another vacuum vessel different from the vacuum vessel for the film deposition, the system becomes larger and poses some problems such as a rise in the fabrication cost or an increase in time necessary for processing the substrate.

### SUMMARY

An object of the present invention is to provide a CVD system not requiring the provision of a special film deposition pre-treatment chamber and therefore reduced in size, shortened in substrate processing time, reduced in fabrication costs, reduced in damage to the active layer, and giving an excellent interface before forming the insulating film, and a substrate cleaning method used for the CVD system.

The CVD system and substrate cleaning method according to the present invention are comprised as follows to achieve the above object.

The CVD system of the present invention is predicated on a system having a plasma generation space divided from the film deposition space and is provided with a plasma generator having a plasma generation chamber separated from a film deposition chamber in which a substrate is arranged. Material gas is directly supplied in the film deposition chamber, and radicals in the plasma are introduced from the plasma generator through introduction holes. A thin film is deposited on the substrate in the film deposition chamber. Further, the CVD system is characterized in that the plasma generator is provided with a cleaning gas feeder. A cleaning gas is introduced through the cleaning gas feeder to produce plasma in the plasma generator and generate radicals, and the radicals are introduced through the introduction holes to the film deposition chamber to strike and thereby clean the substrate. Since a silicon-based film and the like is actually deposited on the surface of the substrate in a preceding process, the surface of the film deposited on the substrate is processed by the radicals as required.

In the above configuration, the CVD system is originally a film deposition system configured as a plasma isolation type. By adding a cleaning gas feeder to the plasma generator, the feeder feeds the required gas into the system to generate plasma. In the system only the radicals in the plasma is taken out to the film deposition chamber through introduction holes provided in the plasma generator. The radicals clean the surface of the film deposited on the substrate. This system uses the plasma isolation type CVD film deposition system. Thereby it is possible to generate plasma for cleaning the substrate in the plasma generator, take out only the radicals to the film deposition chamber, and clean the surface of the film on the substrate.

A substrate cleaning method of the present invention is applied to the method comprising steps of depositing a silicon-based film on a substrate, converting the silicon-based film to a crystalline silicon film by laser annealing, depositing a gate insulating film on the crystalline film by a CVD system with separate film deposition chamber and plasma generation chamber. The substrate cleaning method comprises steps of generating plasma by use of a cleaning gas in the CVD system at a stage before depositing the gate insulating film, and emitting only the radicals in the plasma on the crystalline silicon film to clean its surface. This substrate cleaning method is carried out in the plasma isolation type CVD film deposition system and can clean the surface of the film deposited on the substrate by just radicals.

In the above, the cleaning gas is preferably a gas selected from O₂, H₂, F₂, N₂, dilute gas, and halide gas, or a gas comprised of a suitable mixture of these gases.

According to the above configuration, in the film deposition system using the plasma isolation type CVD method, a mechanism for generating plasma, taking out radicals, and cleaning the surface of the substrate is added in order to clean the substrate using the radicals before film deposition. Accordingly, there is no longer a need to provide a special film deposition pre-treatment chamber. As a result, the system becomes smaller, the substrate processing time is reduced, the fabrication cost is reduced, and the surface of the substrate is cleaned by the radicals. So, the damage to the active layer can be reduced and a good interface can be obtained before forming the insulating film.

### BRIEF DESCRIPTION OF THE DRAWINGS

These and other objects and features of the present invention will become clearer from the following description of the preferred embodiments given with reference to the accompanying drawings, in which:

FIG. 1 is a view of an overall system including a CVD system according to the present invention;

FIG. 2 is a view of an internal structure of an insulating film deposition system and peripheral systems; and

FIG. 3 is a view of a modification of the present invention.

### DETAILED DESCRIPTION OF EMBODIMENTS

Preferred embodiments of the present invention will be explained next based on the attached drawings.

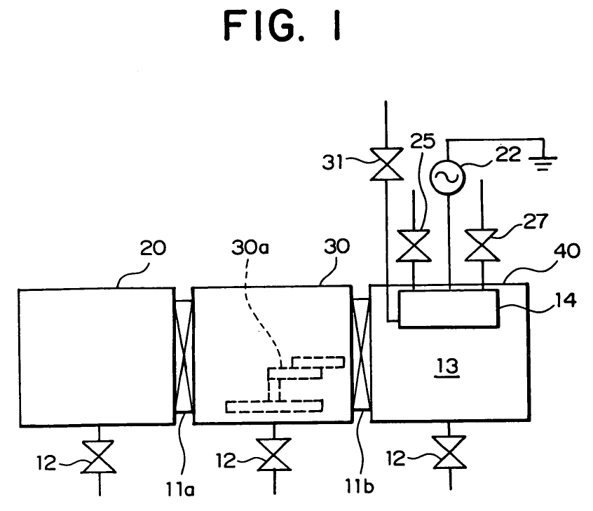

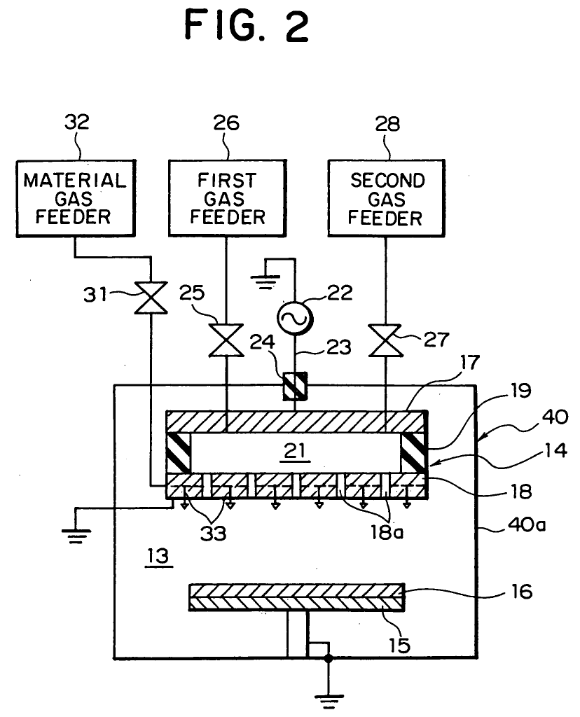

The first embodiment of the present invention will be explained next with reference to FIG. 1 and FIG. 2. In FIG. 1, reference numeral 20 indicates a laser annealing chamber, 30 a loading chamber, and 40 an insulating film deposition chamber. The laser annealing chamber 20 and the insulating film deposition chamber 40 are connected to the loading chamber 30 through gate valves 11a and 11b. Further, evacuation valves 12 are provided at these chambers. Further, an evacuation system (not shown) is connected to each of them. When depositing a film or performing other processes in the chambers, the insides of the chambers 20, 30, and 40 are evacuated by the evacuation system through the evacuation valves 12 and held in the required vacuum states (or reduced pressure states). Note that the loading chamber 30 has built into it a robot arm 30a for loading substrates as shown by the broken lines. The system shown in FIG. 1 is configured as a multi-chamber type system. Further, the system includes for example a silicon-based film deposition chamber. In this chamber, a silicon-based thin film is deposited on the surface of the substrate. In this example, the silicon-based thin film is for example an amorphous silicon film.

The substrate on which the silicon based (or amorphous silicon) film is deposited in the film deposition chamber is loaded into the laser annealing chamber 20. As the loading system, the robot arm 30a in the loading chamber 30 is used. In the laser annealing chamber 20, a laser beam is emitted on the surface of the substrate on which the film is formed. The amorphous silicon film on the substrate is converted to a polycrystalline silicon film by the heat treatment due to the laser beam. Next, the substrate is loaded by the substrate loading robot arm 30a provided in the loading chamber 30 and loaded into the insulating film deposition chamber 40 through the gate valves 11a, 11b. The substrate loaded into the insulating film deposition chamber 40 is placed on the substrate holder arranged at the bottom. In the chambers 20 to 40 shown in FIG. 1, the characterizing portion is the structure of the insulating film deposition chamber 40 shown by a solid line.

The insulating film deposition chamber 40 is a system for forming a gate insulating film (for example, oxide film) on the polycrystalline silicon film on the substrate. The insulating film deposition chamber 40 is provided at the inside top with a plasma generator 14 with a built-in plasma generation chamber separated spatially from the film deposition chamber 13 and is configured as a plasma isolation type CVD film deposition system.

A more detailed structure of the insulating film deposition chamber 40 is shown in FIG. 2. A substrate holder 15 is provided at the bottom of the chamber vessel 40a. The chamber vessel 40a and the substrate holder 15 are connected to the ground. A substrate 16 is placed on the substrate holder 15. A plasma generator 14 is provided above the substrate holder 15. The plasma generator 14 is comprised of a conductive upper plate 17 and lower plate 18 and a circumferential wall 19 made of an insulator. A plasma generation chamber 21 is formed inside. The plasma generation chamber 21 is connected to the film deposition chamber 13 outside the plasma generator 14 through a plurality of through holes 18a formed on the lower plate 18. A high frequency power supply 22 is connected to the upper plate 17. High frequency power is supplied to the upper plate 17. An insulator 24 is provided between the power feed line 23 and the chamber vessel 40. Further, the plasma generator 14 is provided with a first gas feeder 26 for feeding a film deposition gas to the plasma generation chamber 21 through the valve 25 and a second gas feeder 28 for feeding a cleaning gas to the plasma generation chamber 21 through the valve 27. As the film deposition gas, for example, NH₃, N₂, O₂, H₂, Ar, etc. is used. Further, as the cleaning gas, for example, NH₃, CIF₃, CF₄, C₂F₆, H₂, O₂, N₂, F₂, Ar, SF₃, etc. (dilute gas, halide gas, etc.) is used. On the other hand, the lower plate 18 is connected to the ground.

If the film deposition gas is introduced into the plasma generation chamber 21 by the first gas feeder 26 and the high frequency power is supplied from the high frequency power supply 22 to the upper plate 17, the plasma for generating the radicals used for forming the gate insulating film on the surface of the film on the substrate 16 is generated in the plasma generation chamber 21. Further, if the cleaning gas is introduced into the plasma generation chamber 21 by the second gas feeder 28 and high frequency power is supplied from the high frequency power supply 22 to the upper plate 17, plasma for generating radicals used for cleaning the surface of the film on the substrate 16 is generated.

The lower plate 18 is formed to have a plurality of through holes having required diameters across the entire surface of the plate as explained earlier. These through holes 18a pass the radicals generated by the plasma produced in the plasma generation chamber 21 and allow them to diffuse into the film deposition chamber 13. These through holes 18a are set with diameters so that only the radicals can pass through them. Silicon-based material gas (for example, SiH₄) is supplied from a material gas feeder 32 provided with a valve 31 to the lower plate 18. The material gas is introduced into the reserve space formed in the lower plate 18. Next, it is introduced into the film deposition chamber 13 through the plurality of diffusion holes 33.

The operations of the first gas feeder 26 and the second gas feeder 28 are controlled to be selectively executed. In this embodiment, first a cleaning gas is introduced, the surface of the film on the substrate 16 is cleaned, then the film deposition gas is introduced, and a gate insulating film is formed on the surface of the substrate 16.

That is, a substrate 16 with a film treated by laser annealing (polycrystalline silicon film) formed on its surface is placed on the substrate holder 15, then a cleaning gas is introduced into the plasma generation chamber 21 of the plasma generator 14 by the second gas feeder 28 and a high frequency power is supplied from the high frequency power supply 22 to the upper plate 17. Due to this, electric discharge is started at the plasma generation chamber 21 and plasma is generated. As a result, radicals are generated in the plasma. The radicals move through the through holes 18a of the lower plate 18 to the film deposition chamber 13 and the surface of the film deposited on the substrate 16 is cleaned by the radicals. Due to this, it becomes possible to remove the impurities generated on the surface of the film on the substrate after laser annealing.

After the substrate cleaning process is ended and the predetermined conditions are met, the film deposition gas is introduced into the plasma generation chamber 21 of the plasma generator 14 by the first gas feeder 26 and high frequency power is supplied from the high frequency power supply 22 to the upper plate 17. Due to this, an electric discharge is started in the plasma generation chamber 21 and plasma is produced. As a result, radicals are generated in the plasma. The radicals move through the through holes 18a of the lower plate 18 to the film deposition chamber 13. On the other hand, along with the introduction of the radicals, the material gas is introduced into the film deposition chamber 13 from the material gas feeder 32 through the lower plate 18. In the film deposition chamber 13, the radicals and material gas react and as a result a gate insulating film is formed on the surface of the film deposited on the substrate 16.

The plasma isolation type CVD film deposition system according to the present invention preferably includes a vacuum system wherein a plurality of processing are carried out onto a substrate without vacuum breaking, as illustrated in the first embodiment.

According to the above embodiment, an amorphous silicon film is formed in the silicon-based film deposition chamber (not shown) and the amorphous silicon film is converted to polycrystalline silicon film by laser annealing. Next, the substrate is loaded into the insulating film deposition chamber 40 without being exposed to the atmosphere. In the insulating film deposition chamber 40, immediately before forming the gate insulating film, plasma is generated by the plasma generator 14 using the cleaning gas and the surface of the film on the substrate 16 is cleaned by the radicals supplied. Due to this, it is possible to remove impurities caused by laser annealing on the surface of the film on the substrate 16. By just adding a mechanism for generating a cleaning plasma to the plasma generator in an insulating film deposition chamber comprised as a plasma isolation type CVD film deposition system, it is possible to clean the substrate by radicals, the system can be made smaller and less expensive, and the collisions of the charged particles on the surface of the substrate are reduced and the defect rate of the products can be reduced.

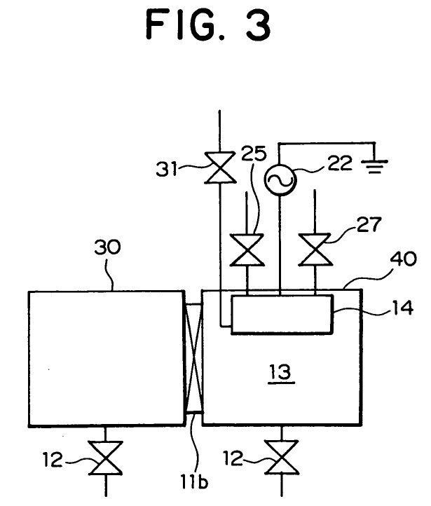

In the above first embodiment, a configuration where the laser annealing chamber 20, the loading chamber 30, and the insulating film-forming chamber 40 are formed integrally is illustrated, but as shown in FIG. 3, it is also possible to combine the loading chamber 30 and the insulating film deposition chamber 40 as a unit (a second embodiment). The configuration in the insulating film deposition chamber 40 is the same as that explained in the first embodiment.

While the invention has been described with reference to specific embodiment chosen for purpose of illustration, it should be apparent that numerous modifications could be made thereto by those skilled in the art without departing from the basic concept and scope of the invention.

What is claimed is:

1. An insulating film manufacturing method comprising:
manufacturing an insulating film using a CVD system, the CVD system including
a chamber having
a film deposition portion and a plasma generating portion,
a partition member for dividing said film deposition portion and said plasma generating portion, said partition defining openings for connecting the film deposition portion and the plasma generation portion,
a substrate holder for holding a substrate,
a high-frequency power source for generating plasma, which is connected to said plasma generating portion,
a first gas feeder for introducing a gas used for film deposition into said plasma generating portion,
a second gas feeder for feeding introducing a halide gas used for cleaning into said plasma generating portion, and
a third gas feeder for introducing a material gas into said plasma generating portion,
wherein said halide gas used for cleaning is introduced to said plasma generating portion before said gas used for the film deposition and said material gas are introduced to said plasma generating portion.

2. An insulating film manufacturing method according to claim 1, wherein said insulating film is a gate insulating film.

3. An insulating film manufacturing method comprising:
manufacturing an insulating film by using a manufacturing system for manufacturing a CVD system, the system including
a CVD system having a chamber, the chamber including
a film deposition portion,
a plasma deposition portion,
a plasma generating portion,
a partition member for dividing said film deposition portion and said plasma generating portion, which has openings for connecting the film deposition portion and the plasma generation portion,
a substrate holder for holding a substrate,
a high-frequency power source for generating plasma, which is connected to said plasma generating portion,
a first gas feeder for introducing a gas used for a film deposition into said plasma generating portion,
a second gas feeder for feeding introducing a halide gas used for cleaning into said plasma generating chamber and
a third gas feeder for introducing a material gas into said plasma generating chamber,
wherein said halide gas used for cleaning to said plasma generating chamber before said gas used for the film deposition and said material gas are introduced to said plasma generating chamber;
a substrate loading chamber; and
a laser annealing chamber.

4. An insulating film manufacturing method according to claim 3, wherein said insulating film is a gate insulating film.
